(19) United States
(12) Patent Application Publication
(10) Pub. No.: US 2021/0342505 A1
(43) Pub. Date: Nov. 4, 2021

(54) APPLICATION OF OPTIMIZED QUANTUM MONTE CARLO SIMULATION METHOD IN STUDYING COMPLEX MAGNETIC SYSTEMS

(71) Applicant: Zhaosen LIU, Jiangsu (CN)

(72) Inventor: Zhaosen LIU, Jiangsu (CN)

(21) Appl. No.: 17/272,646

(22) PCT Filed: Aug. 27, 2019
(86) PCT No.: PCT/CN2019/102764

§ 371 Date: Mar. 1, 2021

(30) Foreign Application Priority Data
Sep. 1, 2018 (CN) 201811019349.4

(51) Int. Cl. G06F 30/20; G06N 10/00

(52) U.S. Cl. CPC G06F 30/20; G06N 10/00

(57) ABSTRACT

The present invention provides an optimized quantum Monte Carlo method. The method comprises the following steps. S1: the spin or magnetic moment in a system Hamiltonian is a quantum mechanical operator, and all physical quantities being calculated according to the quantum theory. S2: initiate all spins' orientations randomly at the beginning. S3: randomly select one spin in each step, and rotating it by a random three-dimensional angle. S4: judge whether the new orientation of the spin is acceptable according to the Metropolis algorithm. S5: if it is acceptable, update the energy states of neighbors. S6: judge whether the current cycle is finished, if not, returning to S3. S7: judge whether the current circle meets a convergence condition or the number of circles is greater than a certain integer, if not returning to S3. S8: calculate and output the magnetic structure and other physical quantities.

### TECHNICAL FIELD

This innovation belongs to the fields of computational physics and computational materials. The related theory, model, methodology and software developed based on it can be used to study the magnetic structures of magnetic systems, and to calculate the magnetization, susceptibility, hysteresis curve and specific heat for each of them.

### BACKGROUND

For several decades, researchers in the world usually have been using classical Monte Carlo (CMC) [1-5] and micromagnetic [6-9] methods to simulate the microscopic magnetic structures of magnetic materials, and to investigate their macroscopic physical properties.

However, these two methods are built upon classical physics. That is, in the models, the spin and magnetic moments are considered as classical vectors with fixed lengths, but can be rotated in space. Obviously, such simple treatment inevitably hinders the accurate description for the considered systems, unfavorably affect both the computational speed and calculated results.

In classical Monte Carlo (CMC) simulations, to let the computing code converge to the equilibrium state at a given temperature T, every spin is rotated continually in space, the energy change before and after the rotation is then compared, and the Metropolis algorithm is employed to decide if the new state of the spin is accepted or not, in order to lower the total energy of the system; after tens of thousands or even up to millions of iterations, averaging is made for each spin over the last tens of thousands of iterations to get that spin-vector value in the equilibrium state; afterwards, the macroscopic physical quantities of the system, such as the magnetization, susceptibility and specific heat are calculated.

In micromagnetic modeling, the considered magnet is usually divided to many small grids, each of the grids has a total magnetic moment \vec{M}, its magnitude Mₛ is assumed to be unchanged in the whole magnet. The variation of \vec{M} as a function of time t can be determined by solving the coupled Landau-Lifshitz-Gilbert (LLG) differential equations [6-9]. Unfortunately, the temperature effects are not considered in the original LLG equation. To overcome this difficulty, Skomski et al assumed that both M_{S} and K₁ (a system parameter) were both temperature dependent [8]. However, how to determine the functions of M_{S}(T) and K₁(T) is not an easy task. Moreover, in small systems of nanoscale, the magnetic moments at different points obviously differ in magnitude. Unfortunately, these differences have been completely ignored in micromagnetic simulations.

Micromagnetic is based upon classical physics as well, it works on the condition that the physical properties of the magnetic systems change slowly and thus continuously in space [10]. If the diameters of magnetic skyrmions, for instance, are in the scale of tens or hundreds of nano-meters, the continuous model is approximately valid, micromagnetic simulations is able to produce rather satisfactory results. However, in recent years, European scientists have discovered that magnetic skyrmions with sizes of several nano-meters could be formed at the interfaces of magnetic multilayers [11-14]. It is these two-dimensional (2D) skyrmions of very tiny sizes at the interfaces that are of great value in data storage. Obviously, in these cases, the classical continuous model becomes invalid, the micromagnetic description is not accurate and reliable any longer [10].

The above described shortcomings of Monte Carlo and micromagnetic methods may inevitably unfavorably affect the computational speed and accuracy of calculated results. We can find in some published papers that the magnetic structures calculated with these two methods show no symmetries of the studied systems. For example, when the long-distance magnetic dipole-dipole interactions are considered in nanodisks, the magnetic structures calculated with the two classical methods exhibited no symmetry at all; and the antiferromagnetic (AFM) skyrmionic lattices (SkLs) formed on 2D infinite square magnets at nonzero temperatures cannot be generated in CMC simulations.

A. W. Sandvik et al has proposed a quantum Monte Carlo (QMC) method before [15,16]. To obtain the partition function of the system, path integral has to be calculated. This theory is quite deliberate, thereby very complicated. Therefore, it can only be used to simulate simple systems of low dimensions consisting of S=1/2 spins. However, magnetic materials can actually be composed of several different atoms, the magnetic moments of these atoms can have different and large values, besides, various complex interactions can be involved. For these real materials, this QMC method cannot be directly applied.

To overcome the above problems, I have developed two quantum computational methods in recent years, where the angular moments or the magnetic moments are treated as quantum mechanical operators instead of classical vectors, all physical quantities, such as magnetic moment, magnetization, total (free) energy and specific heat, at any temperatures are all strictly calculated with quantum.

The first method employs a self-consistent algorithm, thus it is abbreviated as the SCA method. Due to introducing quantum theory, the computing codes are able to converge to the equilibrium states of the system spontaneously, without the need to minimizing the total energy of the system in every computational step as required in CMC simulations, thereby showing great simplicity and directness. With this method, I have successfully simulated the magnetic structures of nanoparticles, nanowires, nanodisks, especially, the ferromagnetic (FM) and AFM vortices formed on nano-plates [17-20].

The second one is the improved quantum Monte Carlo approach, where Metropolis algorithm and quantum magnetic theory are incorporated, which is abbreviated as QMC method. The key points of this QMC method are: the spins in a system Hamiltonian are quantum operators; all physical quantities must be strictly evaluated with quantum formulas; as done in CMC simulations, Metropolis algorithm is also used to judge if the new state of the randomly selected spin after rotation is accepted or discarded. After thousands of iterations, the computational codes may converge to the equilibrium states. By using this method, I have simulated the spin textures of a nanoparticle and a nanodisk, the results agreed with those obtained by means of the SCA approach [21,22].

In both CMC and QMC simulations, to determine if the new state of the randomly selected spin is accepted or not, the total energy change incurred by the rotation has to be calculated [4]. If the studied magnet is quite small, or the long-distance magnetic dipole-dipole interaction has to be considered in such a case, it is seemly possible to calculate the total-energy change of the whole system in every computing step. However, if the system contains great many of spins, to calculate the change of total energy in every computing step will be very time-consuming. Fortunately, rotating the selected spin only affects energy change locally. Being influenced by Ising model, when implementing computing codes, peoples often only note this point, but neglect another important fact, that is, the rotation of the spin has also changed the energy states of other spins in the local area. This careless may seriously slow down computation, even give rise to incorrect convergence.

For simple magnetic systems, if the states of local spins are not updated immediately, the equilibrium state of the system can be estimated approximately after thousands of loops by averaging the spins over the last hundreds of iterations, or reasonable magnetic structures can be obtained by adopting other remedy measures in the computing process as done for the nanoparticle and nanodisk with the QMC method [21,22]. Obviously, these temporary expedients have considerably slowed down the computational speed. Especially, it is found recently that when complicated interactions, such as Dzyaloshinsky-Moriya interaction (DMI), are involved, these temporarily adopted methods cannot guarantee to produce correct magnetic textures.

Based on the above analysis, the improved quantum Monte Carlo method is further optimized in this invention, which is then used here to simulate 2D FM and AFM skyrmionic lattices of the Bloch- and Néel-types, in order to explain its applicability, justify its correctness, and build solid foundation for its general applications in future.

### REFERENCES

[1] Kurt Binder, Dieter Heermann, Monte Carlo Simulation in Statistical Physics, An Introduction, 5-th edition, Springer, 2010.
[2] H. D. Rosales, D. C. Cabra, and P. Pujol, Three-Sublattice Skyrmion Crystal in the Antiferromagnetic Triangular Lattice, Phys. Rev. B 92 (2015) 214439.
[3] R. Keesman, M. Raaijmakers, A. E. Baerends, G. T. Barkema, and R. A. Duine, Skyrmions in Square-Lattice Antiferromagnets, Phys. Rev. B 94 (2016) 054402.
[4] D. Hinzke, U. Newak, Monte Carlo Simulation of the Magnetization Switching in a Heisenberg Model for Small Ferromagnetic Particles, Computer Physics Communications, 121-122 (1999) 334.
[5] E. Y. Vedmedenko, H. P. Oepen, A. Ghazali, J.-C. S. Lévy, and J. Kirschner, Magnetic Microstructure of the Spin Reorientation Transition: A Computer Experiment, Phys. Rev. Lett. 84 (2000) 5884.
[6] W. F. Brown, Micromagnetics, New York: Interscience, 1963.
[7] R. H. Kodama, A E Beikwitz, Atomic Scale Magnetic Modelling of Oxide Nanoparticles, Phys. Rev. B 59 (1999) 6321.
[8] R. Skomski, P. Kumar, George C. Hadjipanayis, and D. J. Sellmyer, Finite-Temperature Micromagnetism, IEEE Transactions on Magnetics 49 (2013) 322.
[9] Ph. Depondt, J.-C. S. Lévy, F. G. Mertens, Vortex Polarity in 2D magnetic Dots by Langevin Dynamics Simulations, Phys. Lett. A 375 (2011) 628-632.
[10] Magnetic skyrmion, https://en.wikipedia.org/wiki/Magnetic skyrmion
[11] S. Heinze, K. von Bergmann, M. Menzel, J. Brede, A. Kubetzka, R. Wiesendanger, G. Bihlmayer, and S. Blügel, Nat. Phys. 7 (2011) 713-718.
[12] B. Dupé, G. Bihlmayer, S. Blügel, and S. Heinze, Nat. Commun. 7 (2016) 11779.
[13] J. Hagemeister, D. Iaia, E. Y. Vedmedenko, K. von Bergmann, A. Kubetzka, and R. Wiesendanger, Phys. Rev. Lett. 117 (2016) 207202.
[14] J. Hagemeister, N. Romming, K. von Bergmann, E. Y. Vedmedenko, R. Wiesendanger, Nat. Commun. 6 (2015) 8455.
[15] A. W. Sandvik, Phys. Rev. B 56 (1997) 11678.
[16] A. W. Sandvik, Computational Studies of Quantum Spin Systems, arXiv: 1101.3281v1[cond-mat.str-el] 17 Jan. 2011.
[17] Z.-S. Liu, M. Diviš, and V. Sechovský, Magnetism of PrAl2 Nanoparticle Investigated with a Quantum Simulation Model, J. Phys.: Condens. Matter 23 (2011) 016002.
[18] Z.-S. Liu, V. Sechovský, and M. Diviš, Magnetism of DyNi2B2C Nano-Particle Investigated with a Quantum Simulation Model, Phys. Status Solidi B, 249 (2012) 202-208.
[19] Z.-S. Liu, H. Ian, Effects of Dzyaloshinsky-Moriya Interaction on Magnetism in Nanodisks from a Self-Consistent Approach, J. Nanopart. Res. (2016) 18:9.
[20] Z.-S. Liu, H. Ian, Numerical Studies on Antiferromagnetic Skyrmions in Nanodisks by Means of a New Quantum Simulation Approach, Chem. Phys. Lett. 649 (2016) 135.
[21] Z.-S. Liu, V. Sechovský, and M. Diviš, Mutual Verification of Two New Quantum Simulation Approaches for Nanomagnets, Physica E 62 (2014) 123-127.
[22] Z.-S. Liu, O. Ciftja, X.-C. Zhang, Y. Zhou, H. Ian, Vortical Structures for Nanomagnetic Memory Induced by Dipole-Dipole Interaction in Monolayer Disks, Superlattices & Microstructures, 117 (2018) 495-502.
[23] X.-Z. Yu, Y. Onose, N. Kanazawa, J. H. Park, J. H. Han, Y. Matsui, N. Nagaosa, Y. Tokura, Nature, 465 (2010) 901
[24] A. O. Leonov, M. Mostovo, Multiply Periodic States and Isolated Skyrmions in an Anisotropic Frustrated Magnet, Nat. Commun. 6 (2015) 8275

Contents of Invention

This invention aims at providing an optimized quantum Monte Carlo simulation method, which can be used to simulate the microscopic magnetic structures of complex magnetic systems, investigate their macroscopic physical properties, and thereby to overcome the difficulty of slow or incorrect convergence that may occur in simulations when classical computational methods are employed.

Implementation of the computing program comprises the following steps:

S1: Quantizing the system Hamiltonian, that is, the spins appearing in the Hamiltonian are treated as quantum operators instead of classical vectors;

S2: Starting simulation at temperature TO, which is above the magnetic critical temperature, so all spins are initiated to be randomly orientated;

S3: In every simulating step, a spin is randomly selected, then rotated randomly by a three-dimensional (3D) angle;

S4: Metropolis algorithm is employed to determine if the new orientation of the rotated spin is accepted or not; if accepted, the energy states of other local spins are immediately updated and computation continues to the next step; otherwise, the next step is directly executed;

S5: Judging if the current computing iteration can be finished, that is, if the number of the simulating steps is equal to the number of the total spins, the next step is executed, otherwise, returning back to S3.

S6: Judging if the converging condition is satisfied, or if the number of the iterations is larger than an integer; if yes, executing the next step, otherwise, returning back to S3;

S7: The microscopic magnetic structure and macroscopic physical quantities are evaluated with quantum formulas, and then outputted;

The further technical scheme of this invention also includes the following steps:

S8: Let T=T−ΔT to lower temperature, where ΔT is the temperature-step length, if T is less than the given lowest temperature T_{f}, simulation is completed; otherwise, return back to S3.

Other measures are taken in S4:

S4-1: If the spin is at an edge of the 2D square chosen for simulation, the periodical boundary conditions have to be applied;

S4-2: The thermal averages of the spins and their energies are calculated with quantum formulas.

The key technique of this invention is that: the energy states of all local spins are updated immediately once the new orientation of the rotated spin is accepted, which helps greatly for the computing code to converge quickly to equilibrium states of the system.

One characteristic of this invention is that: the system state reached in the last one iteration after convergence represents accurately the equilibrium state of the system at the temperature, without the need to take averages of the spins over tens of thousands of iterations as that is conventionally done in CMC simulations.

Another feature of this invention is that: the OQMC method enable us to accurately calculate the magnitudes and orientations of all spins everywhere in the systems in detail at any temperatures.

The purpose of this invention is to present a new simulating tool, i.e., the optimized quantum Monte Carlo method, to simulate and investigate various magnetic materials, such as the 2D FM and AFM SkLs that are shown below in the Examples.

A favorable effect of this invention is proved to be that: implementing both quantum theory and immediate updating technique into the computing code can not only considerably expedite the converging speed, but also overcome the difficulty of slow or incorrect convergence that may occur in simulations as classical simulation methods are employed.

### BRIEF DESCRIPTION OF THE DRAWINGS

FIG. 1 is a program flowchart that describes how the optimized quantum Monte Carlo is implemented.

FIG. 2 is a 2D FM SkL of the Bloch-type obtained with the OQMC method.

FIG. 3 is a 2D AFM SkL of the Bloch-type obtained with the OQMC method.

FIG. 4 is the 2D AFM SkL of the Bloch-type shown in FIG. 3 projected onto the xy-plane.

FIG. 5 is a 2D FM SkL of the Néel-type obtained with the OQMC method.

FIG. 6 is a 2D AFM SkL of the Néel-type obtained with the OQMC method.

### DESCRIPTION OF THE EMBODIMENTS

Description for OQMC Method

I. The Optimized Metropolis Algorithm

It is assumed that there are N spins in the system, a simulation is started at high temperature T₀. At temperature T, the following iterating steps are involved:

1. A spin \vec{S}ᵢ is randomly selected;

2. This spin is rotated randomly by a solid angle in space;

3. The energy change ΔEᵢ caused by the rotation is calculated;

4. Calculating pᵢ=exp(−ΔEᵢ/k_{B}T);

5. A random number rᵢ is generated;

6. If rᵢ<pᵢ, the new state of \vec{S}ᵢ is accepted, and the energy states of local spins are immediately updated;

7. If rᵢ≥pᵢ, the new state of \vec{S}ᵢ is discarded;

8. If the number of simulating steps is less than N, return back to 1.

9. If the converging criterion is not satisfied, or the iteration number is less than a given large integer, return back to 1.

10. Calculating the magnetic structure and the macroscopic properties of the system at the temperature with quantum formulas, and outputting these data.

In the above process, both \vec{S}ᵢ and ΔEᵢ are all calculated according to quantum theory. Especially, by comparing the results obtained with several different schemes, it can be concluded that the updating measure described in step 6 is the key technique to achieve optimization and improve computing efficiency.

II. 2D Systems in Presence of Dzyaloshinsky-Moriya Interaction

For such a system, if an external magnetic field is applied perpendicularly to the 2D plane, SkLs can be induced on the surface or interface. The Hamiltonian of the system can be written as

$$H = - \frac{1}{2} ( {\sum }_{〈 ij 〉} {J}_{ij} {\vec{S}}_{i} \cdot {\vec{S}}_{j} - {\sum }_{〈 ij 〉} {\vec{D}}_{ij} \cdot ( {\vec{S}}_{i} \times {\vec{S}}_{j} ) ) - {K}_{A} {\sum }_{i} {( {\vec{S}}_{i} \cdot {\vec{n}}_{i} )}^{2} - {μ}_{B} {g}_{J} {\sum }_{i} \vec{B} \cdot \vec{{S}_{i}} \qquad ( 1 )$$

Here, the first term represents the Heisenberg exchange interaction (HEI), the second term denotes the Dzyaloshinsky-Moriya Interaction (DMI), the third term stands for the uniaxial anisotropic interaction that is normal to the 2D plane or interface, and the last one is the interaction of the magnetic system with the applied magnetic field. Jᵢⱼ and \vec{D}ᵢⱼ specify the strengths of HEI and DMI between the neighboring i-th and j-th spins. If Jᵢⱼ>0, the magnetic coupling is ferromagnetic; If Jᵢⱼ<0, the coupling is antiferromagnetic. \vec{D}ᵢⱼ=D\hat{r}ᵢⱼ (\hat{r}ᵢⱼ is the unit vector pointing from the i-th spin to the i-th spin), the formed skyrmions are the Bloch-type; \vec{D}ᵢⱼ=D\hat{r}ᵢⱼ×\hat{z}, where \hat{z} is the unit vector along the z-direction, the induced skyrmions are the Néel-type.

III. 2D Systems with DMI and Anisotropic Interaction of Compass-Type

In such a system, except the HEI and DMI, anisotropic interaction of the compass-type is also present, its Hamiltonian can be expressed with

$$H = - \frac{1}{2} {\sum }_{〈 ij 〉} {J}_{ij} {\vec{S}}_{i} \cdot {\vec{S}}_{j} + \frac{1}{2} {\sum }_{〈 ij 〉} {\vec{D}}_{ij} \cdot ( {\vec{S}}_{i} \times {\vec{S}}_{j} ) + {A}_{1} {\sum }_{i} [ {( {S}_{i}^{x} )}^{4} + {( {S}_{i}^{y} )}^{4} + {( {S}_{i}^{z} )}^{4} ] + {A}_{2} {\sum }_{i} ( {S}_{i}^{x} {S}_{i + a}^{x} + {S}_{i}^{y} {S}_{i + a}^{y} ) , \qquad ( 2 )$$

where the last two terms denote the compass-type anisotropy. In such a system, SkLs can be formed spontaneously below the critical temperature in the absence of external magnetic field.

IV. The Key Technical Elements of OQMC Method

In previous studies, I have adopted following measures:

(1) Quantum theory is introduced, that is, the spins in a Hamiltonian are quantum operators instead of classical vectors, all physical quantities are calculated with quantum formulas;

(2) In every simulation step, Metropolis algorithm is employed to decide if the new state of the rotated spin is accepted or discarded;

(3) The thermal expectation values of all spins are calculated by averaging the spins over the last hundreds of iterations.

Since the averaged value for every spin has to be calculated in (3), such a simulation is not only very time-consuming, but the computational effects are also not ideal, Therefore, I adopt the following important optimizing techniques in this invention:

(4) If the new state of the randomly selected spin is accepted, the energy states of other spins in the local area are all updated immediately.

In order to generate SkLs on 2D magnets,

(5) Periodical boundary conditions are imposed;

(6) External magnetic field is applied perpendicularly to the 2D plane;

(7) When the compass-type anisotropic interaction is also involved, SkLs can be formed spontaneously in the absence of external magnetic field below the critical temperature.

The technique adopted in (4) efficiently helps for the computing code to converge very quickly, and the state reached in the last one iteration represents accurately the equilibrium state of the system at any temperature, without the need to average the spins over great many iterations, thus accelerating computational speed considerably.

To manifest the necessity and justify correctness of the optimizing technique described in (4), the following schemes have been adopted to perform simulations for comparison:

(a) Non-optimized Metropolis algorithm is employed;

(b) Non-optimized Metropolis algorithm is employed, but the states of all spins are updated after every iteration is finished;

(c) Optimized Metropolis algorithm is employed, i.e., once the new state of the rotated spin is accepted, the energy states of other local spins are updated immediately.

Using the above schemes separately and one combination, I have simulated the 2D SkLs of the Bloch-type with J=1 K, D=1.02733 K, B=0.12 Tesla. Consequently:

If scheme (a) is used, no SkL can be produced in whole temperature region.

If scheme (b) is used, the computing code is able to converge ideally while T>0.3 K, but converge badly in low temperature region. More specifically, while 3.1≥T≥0.3 K, the calculated SkLs look fine; but at T=0.1 K, the generated spin texture consists of both skyrmions and bimerons instead.

If scheme (c) is employed, the computing code converges quickly, and produces well periodical and symmetric SkLs in the whole temperature region T≤3.1 K.

If (b) and (c) schemes are both employed, the calculated results are almost same as those obtained by using only (c) scheme. The only difference is that the calculated SkLs are translated with each other in the 2D plane. Moreover, the calculated curves of the macroscopic thermal quantities, such as the total (free) energy, etc., coincide in the whole temperature region with the corresponding ones got by using (c) scheme alone.

Therefore, we can conclude that scheme (c) is essential and indispensable for quick and correct convergence.

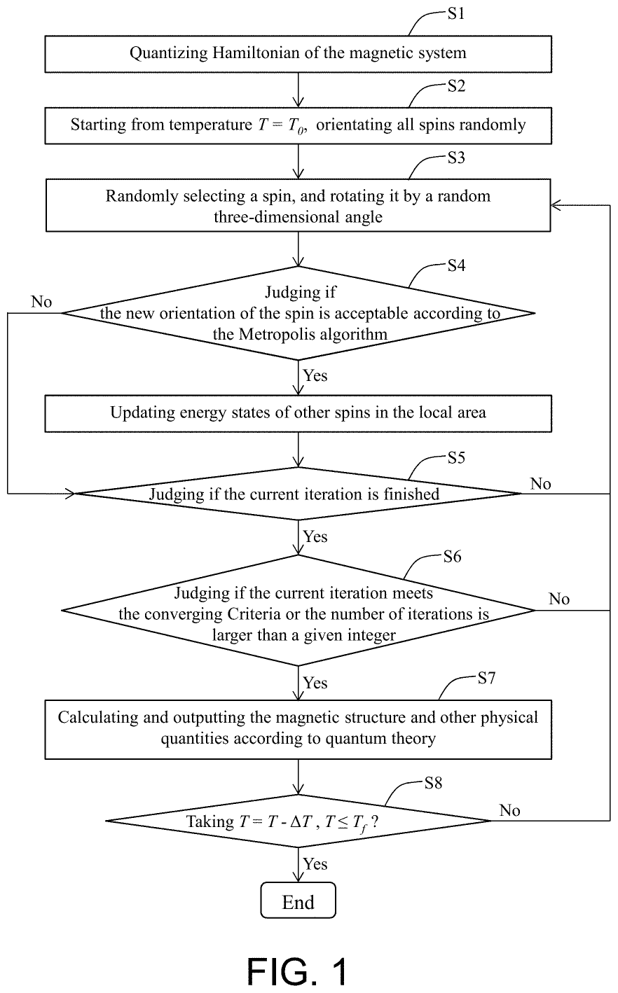

FIG. 1 is the Program Flowchart illustrating how the OQMC is implemented, which is described in detail as below:

Step 1, Firstly, quantizing the system Hamiltonian, that is, the spins or angular moments appearing in the Hamiltonian are treated as quantum operators;

Step 2, Simulation is started at temperature T₀ that is above the critical magnetic temperature, all spins are initiated to be randomly orientated.

Step 3, In every simulating step, a spin is randomly selected, and rotated by a random solid angle in space.

Step 4, Metropolis algorithm is employed to determine if the new state of the rotated spin is accepted or discarded; if accepted, the energy states of other local spins are immediately updated, and the next step is then executed; otherwise, the next step is directly performed.

Step 5, Judging if the current iteration can be finished, that is, if the number of steps is equal to N, next step is then executed; otherwise, returning back to Step 3;

Step 6, Judging if the current iteration meets the converging criterion, that is, if the relative change of any spin vector in two successive iterations is less than a given small number 6, or the number of iterations is larger than a given integer, executing to the next step; otherwise, return back to Step 3;

Step 7, The microscopic magnetic structure and macroscopic physical quantities of the system are calculated with quantum formulas, and outputted afterwards;

Step 8, Let T=T−ΔT to lower temperature, where ΔT is the temperature-step length, if T is smaller than the given lowest temperature T_{f}, simulation finishes, otherwise, return back to Step 3.

V. Favorable Effects of This Invention

1. Quantum theory is introduced in this invention, which consequently overcomes the classical limitations faced by CMC and micromagnetic methods that have been widely used for several decades. Therefore, it is a significant theoretical progress.

2. Magnetic properties are originated from the microscopic interactions among the atoms and ions in the material, and these interactions are determined by the distributions of both localized and conduction electrons. Obviously, only quantum theory is able to accurately describe the magnetic structures and macroscopic physical quantities, therefore the theory is really necessary to be introduced and applied.

3. The application of quantum theory makes code implementation much simpler and easier, and helps the program run very efficiently. For example, when rare earth magnets are studied, the interaction of crystal electric field (CEF) have to be considered. For such a system, if CMC or micromagnetic method is employed, it is obviously inconvenient and inaccurate to describe the complicated CEF interactions and the variation of magnetic structures with classical vectors. In contrast, if the CEF interactions are expressed in terms of quantum operators, and all physical quantities are evaluated with quantum theory, the computing codes can be very easily implemented [18].

Moreover, using the CMC method, previous authors could only generate a single skyrmion in a very tiny antiferromagnet of the square crystal structure, but they had difficulty to produce AFM SkLs in such 2D systems. In contrast, by means of the OQMC method, I am able to easily generate the AFM SkLs of both Bloch- and Néel-types on 2D infinite square magnets at non-zero temperatures. These results will be presented below in the Examples.

Besides, when the magnetic dipole-dipole interaction of the spins are present in nanodisks, previous authors had difficulty to generate symmetric vortical spin textures with both CMC and micromagnetic methods. In contrast, by means of the two quantum methods, I was able to produce well symmetric vortical spin textures in such nanodisks, and the results agreed well with each other [22].

4. The OQMC method proposed in this invention ensures correct convergence. Otherwise, as explained in Example 4, even the states of all spins are updated after every iteration is completed, AFM SkLs of Néel-type can only be produced in temperature region 0.8 K≤T≤1.9 K, no correct spin textures can be generated if temperature falls further.

5. The OQMC method proposed in this invention considerably accelerates the computational speed. For instance, to simulate AFM SkLs formed on 2D magnets, a square of 28×28 lattice sites was chosen and the periodical boundary conditions were imposed. From T=2.5 K down to 0.1 K (T is scaled in fact), simulations were carried out for 25 temperature points, and consequently 18 AFM SkLs were produced below the critical temperature. Using a portable Thinkpad computer of T470P type, it took about 11 minutes to complete simulations. In order to achieve high computing accuracy, the converging criteria δ was assigned to 10⁻⁶. If a somehow larger δ is used, much shorter time will be needed.

6. One merit of the OQMC method proposed in this invention is that: the equilibrium state of the studied system at any temperature T can be achieved in the last one iteration, there is no need to take averages of the spins over the last tens of thousands of iterations as those conveniently done in CMC simulations.

VI. Difference Between OQMC and SCA Methods

1. What They Share in Common

(1) Quantum theory is applied in the both methods, that is, the spins or angular moments in the system Hamiltonian are quantum operators instead of classical vectors.

(2) All physical quantities are calculated strictly with quantum formulas, rather than being obtained by simple algebraic average that is conventionally done in CMC simulations.

(3) Usually, the both methods can be applied to same systems, and generate almost same results. Actually, in the four examples given below, the results obtained with the two methods show very good similarities correspondingly though the temperatures chosen for simulations differ somehow.

2. How They Differ

(1) The self-consistent algorithm is employed in the SCA method, it is able to converge spontaneously to the equilibrium state without the need of elaborate and artificial manipulation for the spins.

(2) Metropolis algorithm is employed in the OQMC method. That is, in every step, a spin is randomly selected, and rotated in space randomly, the algorithm is then used to judge if the new state of the spin is accepted or not, and the states of the local spins are updated when necessary.

Therefore, the two methods are completely different.

### EXAMPLES

To explain the applicability and justify the correctness of the OQMC method, computations are carried out to simulate 2D FM and AFM SkLs of both Bloch- and Néel-types. As described above, the Hamiltonian of such a system can be expressed as

$$H = - \frac{1}{2} ( {\sum }_{〈 ij 〉} {J}_{ij} {\vec{S}}_{i} \cdot {\vec{S}}_{j} - {\sum }_{〈 ij 〉} {\vec{D}}_{ij} \cdot ( {\vec{S}}_{i} \times {\vec{S}}_{j} ) ) - {K}_{A} {\sum }_{i} {( {\vec{S}}_{i} \cdot {\vec{n}}_{i} )}^{2} - {μ}_{B} {g}_{J} {\sum }_{i} \vec{B} \cdot \vec{{S}_{i}} \qquad ( 1 )$$

Here, if Jᵢⱼ>0, the magnetic coupling is ferromagnetic; If Jᵢⱼ<0, the coupling is antiferromagnetic. When \vec{D}ᵢⱼ=D\hat{r}ᵢⱼ, the formed skyrmions are the Bloch-type; If \vec{D}ᵢⱼ=D\hat{r}ᵢⱼ×\hat{z}, the induced skyrmions are the Néel-type. To simplify the model, in the four examples, only the interactions among the nearest neighboring spins are considered, and the strengths of HEI and DMI are assumed to be same everywhere in the systems, i.e., Jᵢⱼ=J, Dᵢⱼ=D always.

### Example I: 2D FM Skymion Crystal of Bloch-Type

Let's consider a 30×30 square lattice with each site occupied by an S=1 spin. To mimic the infinite size of the 2D magnet, periodical boundary conditions have to be imposed. Uniaxial anisotropy is not considered here, J=1 K and D=1.02733 are taken to perform simulations. Thus, we know from the related theory that, when a weak external magnetic is applied perpendicularly to the 2D magnet, FM SkLs can be induced, and the periodicity 2 of the spin crystal is equal to 10 in the unit of the lattice parameter along the two axes.

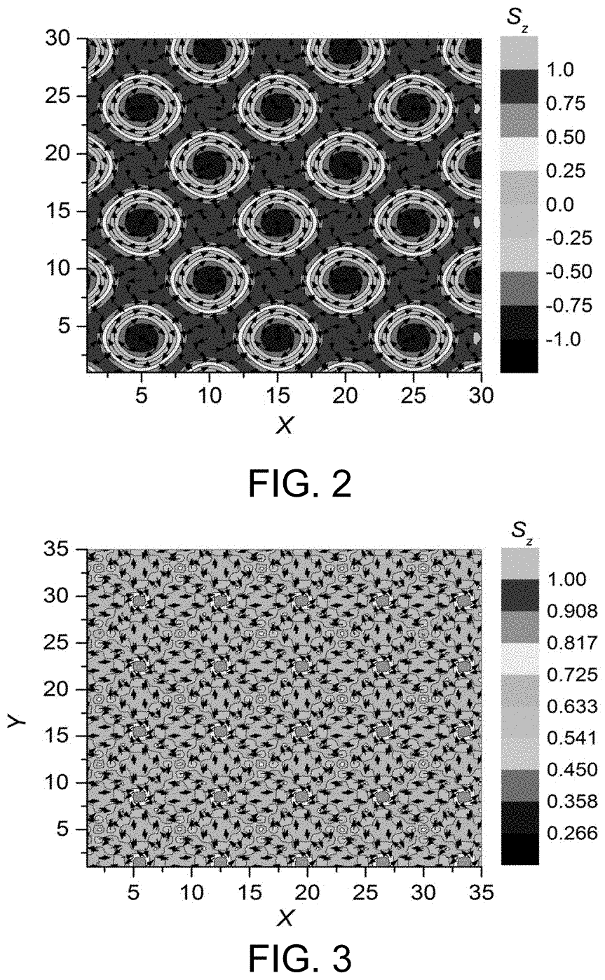

FIG. 2 displays the FM SkL of the hexagonal-closely-packed (HCP) pattern calculated at B=0.12 Tesla and T=1 K. It is well symmetric, and the periodicity λ=10 along the two axes, agreeing with theoretical and experimental results [23].

Here, the external magnetic field is exerted along the z-axis, but the z-component of every spin in the core area of every skyrmion is parallel to −z, whereas those in the marginal area are aligned in the opposite direction. Therefore, these particle-like spin textures are strictly skyrmions. Moreover, every skyrmion swirls clockwisely, and is surrounded by four neighboring vortices that curl anti-clockwisely in the opposite direction, so that the total energy of the magnet is minimized, and the spin texture is better stabilized.

### Example II: 2D AFM Skymionic Crystal of Bloch-Type

In this case, let's consider a 2D 35×35 AFM magnet of the square structure, where each site is occupied by an S=1 spin. The parameters are taken as J=−1 K and D=1 K (D/J=−1), respectively, in simulations, but uniaxial anisotropy is not considered. Periodical boundary conditions are also imposed to mimic the infinite size of the system. It is found in simulations that, within the perpendicularly applied magnetic fields with strengths in the range 3.9 Tesla≤B≤4.1 Tesla, AFM SkLs can be induced in a low temperature region T<1.8 K. If the external magnetic field is enhanced or weaken considerably beyond this region, AFM textures disappear and are replaced by other AFM textures.

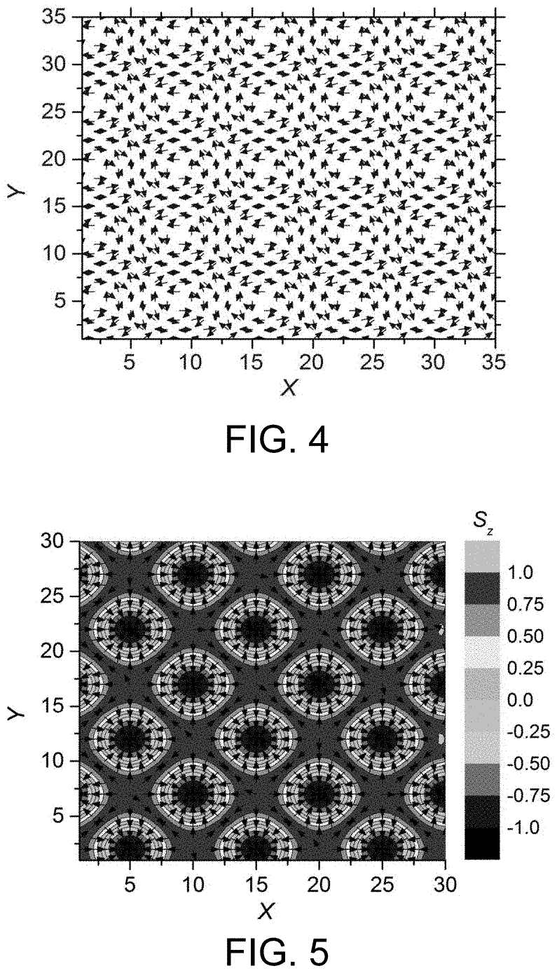

FIGS. 3 and 4 show the AFM SkL obtained at B=4 Tesla and T=1 K. It exhibits good symmetry, and the periodicity λ=7 in the unite of lattice constant. In the small core area of a skyrmion, the z-component of each spin is smallest in average, whereas those of the spins at the middle sites of the lines connecting the two nearest AFM skyrmions in the two diagonal directions of the square are largest, and the xy-projections of a pair of neighboring spins are nearly opposite in the plane. All of these endow the AFM features to the 2D SkL.

In Example I, B₁=0.12 Tesla; in Example 2, B₂=4 Tesla. In these two cases, D/|J| values are very close, but B₂/B₁≈33.333. Therefore, to observe AFM SkLs, magnetic fields about 33.33 times stronger have to be applied. Moreover, AFM SkLs are induced in a relatively narrow B region, suggesting that these AFM spin textures are not very stable. These make AFM SkX hard to be produced and observed in experiments.

### Example III: 2D FM Skymionic Crystal of Néel-Type

In this example, an FM square magnet of 30×30 sites is considered, each one is occupied by an S=1 spin, and periodical boundary conditions are also applied to mimic the infinite size of the 2D magnet. The same set of parameters, J=1 K and D=1.02733 K, as in Example I, are used. The spin texture simulated at T=1 K and B=0.12 Tesla is depicted in FIG. 5. Interestingly, though this SkL is the Néel-type, as that one of the Bloch-type shown in FIG. 2, now the periodicity λ is also equal to 10 along the two axes, and the induced 18 FM skymions are formed in the HCP pattern as well. In the core area of every skyrmion, the z-component of every spin is aligned in −z direction, that is opposite to the applied magnetic field; but in the marginal area, the z-component of every spin is along the direction of external magnetic field. Therefore, these particle-like spin textures are typical skyrmions. In comparison with those of Bloch-type, the xy-components of the spins inside a Néel-type skymrion all converge to its center.

### Example IV: 2D AFM Skymionic Crystal of Néel-Type

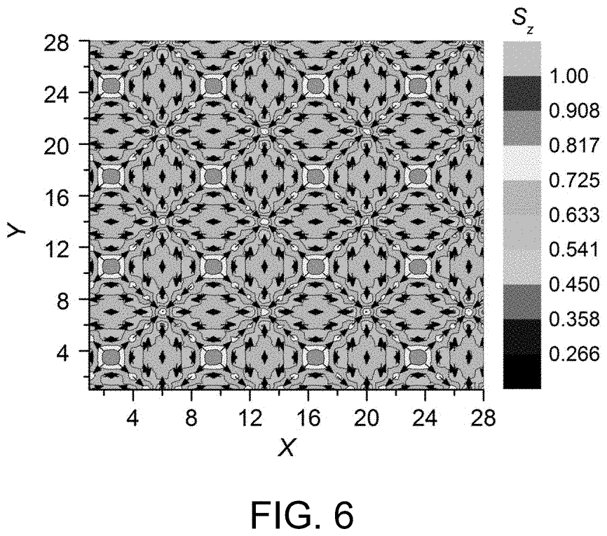

To carry out simulation, an AFM magnet with 28×28 lattice sites is considered, each site is also occupied by an S=1 spin, once again, periodical boundary conditions are imposed for the same purpose. The set of parameters J=−1 K, D=1 K and B=4 Tesla, that are same as Example II, are used. FIG. 6 shows the AFM SkL obtained in low temperature region. In comparison with FIGS. 3 and 4, though there the AFM SkL was Bloch-type, this one is Néel-type, the two AFM SkLs are all in the square pattern, and their wavelengths are all equal to 7. Once again, the z-component of every spin in the core region is smallest in average, whereas those of the spins at the middle sites of the lines connecting the two AFM skyrmions along the two diagonal directions of the square are largest, and the xy-projections of a pair of neighboring spins are aligned nearly opposite in the plane. All of these characters endow the AFM features to this Néel-type AFM SkL. Except the marginal area, the xy-projections of every neighboring pair of spins inside the AFM skyrmions align oppositely in the radial directions. Therefore, this spin crystal is typically AFM Néel-type.

With J=−1, D/|J|=1, and H/|J|=4, R. Keesman and his coworkers were able to generate a single AFM skyrmion in a finite-size 8×8 AFM magnet of the square crystal structure in CMC simulations [3]. However, Tretiakov et al have showed theoretically that AFM skyrmions could exist at non-zero temperatures, and they were much stabler when placed in external magnetic fields [24]. Therefore, Examples II and IV suggest that when skyrmion sizes are very small, classical description becomes inaccurate and unreliable, thus quantum theory must be applied.

Moreover, FIG. 2 and FIG. 5 form a dual pair, FIG. 4 and FIG. 6 form another dual pair. This shows a magic symmetry governed by natural laws, and justifies the correctness of the OQMC method and calculated results presented above.

As temperature or the strength of applied magnetic field varies, the shapes of skyrmions and wavelengths of the SkLs change. To shorten text length, only a few typical calculated spin textures have been displayed here.

Obviously, above described figures are just a few examples, so they cannot limit the protecting extent of this invention. The OQMC method can only be applied to study magnetic systems of finite nano-sizes, but also to investigate 2D, 3D, and almost all sorts of magnetic materials in general. Therefore, any modification, substitution and improvement in the spirit and principle of this invention are in the scope of protection, thus are all prohibited.

1. An optimized quantum Monte Carlo (OQMC) method provided in this invention, comprising:
S1, quantizing a system Hamiltonian, that is, spins or magnetic moments appearing in the Hamiltonian are considered as quantum operators;
S2, simulation being started at temperature T₀ that is above the magnetic critical temperature, so all spins of the system are randomly oriented in space;
S3, at the beginning of every simulating step, always randomly selecting a spin, and then rotating randomly by a 3D solid angle in space;
S4, using a Metropolis algorithm to decide if the new orientation of the spin is accepted or not; if accepted, the energy states of other local spins are undated, and then computation continues to the next step; otherwise, the next step is executed directly;
S5: judging if the current computing iteration can be finished, that is, if the number of the simulating steps are equal to the number of the total spins, the next step is executed, otherwise, returning back to S3;
S6: judging if the converging condition is satisfied, or if the number of the iterations are larger than an integer; if yes, the next step is executed, otherwise, returning back to S3;
S7, calculating a microscopic magnetic structure and other macroscopic physical quantities with quantum theory, then outputted.

2. The OQMC method according to claim 1, wherein the OQMC method further comprising:
S8, letting T=T−ΔT to lower temperature, where ΔT is the temperature step length; if T is less than the given lowest temperature T_{f}, simulation is completed, otherwise return back to S3.

3. The OQMC method according to claim 2, wherein S4 further comprises:
S4-1, if the spin is at an edge of the square chosen for simulations, periodical boundary conditions must be applied;
S4-2, thermal averages of every spin and its energy are calculated with quantum formulas.

4. The OQMC method according to claim 3, wherein in every simulating step, the energy states of the local spins are updated when necessary, so as to describe the physical process really going on in the system, thus the computing code can converge quickly to the equilibrium state, thereby overcoming the difficulty of slow converging or non-converging that may be faced by the classical methods.

5. The OQMC method according to claim 4, wherein the OQMC method is able to calculate the magnitudes and orientations of all spins in the system at any temperatures.

6. The OQMC method according to claim 1 has been successfully applied to simulate both ferromagnetic and antiferromagnetic 2D skyrmionic lattices (SkLs) of the Bloch- and Néel-types.

7. The OQMC method according to claim 2 has been successfully applied to simulate both ferromagnetic and antiferromagnetic 2D SkLs of the Bloch- and Néel-types.

8. The OQMC method according to claim 3 has been successfully applied to simulate both ferromagnetic and antiferromagnetic 2D SkLs of the Bloch- and Néel-types.

9. The OQMC method according to claim 4 has been successfully applied to simulate both ferromagnetic and antiferromagnetic 2D SkLs of the Bloch- and Néel-types.

10. The OQMC method according to claim 5 has been successfully applied to simulate both ferromagnetic and antiferromagnetic 2D SkLs of the Bloch- and Néel-types.
